(19) United States
(12) Patent Application Publication
(10) Pub. No.: US 2025/0212576 A1
(43) Pub. Date: Jun. 26, 2025

(54) LIGHT EMITTING DISPLAY DEVICE

(71) Applicant: LG DISPLAY CO., LTD., Seoul (KR)

(72) Inventors: Young-Hoon SON, Paju-si (KR); Mi-So KIM, Paju-si (KR)

(73) Assignee: LG DISPLAY CO., LTD., Seoul (KR)

(21) Appl. No.: 18/921,510

(22) Filed: Oct. 21, 2024

(30) Foreign Application Priority Data
Dec. 26, 2023 (KR) 10-2023-0191301

(51) Int. Cl. H01L 33/62; H01L 25/16; H01L 33/50

(52) U.S. Cl. CPC H10H 20/857; H01L 25/167; H10H 20/8514

(57) ABSTRACT

A light emitting display device includes: first to third subpixels of different colors; a partition wall of an overhang structure along a boundary between the first subpixel and the second and third subpixels, and including a protrusion portion; a connection electrode under the protrusion portion at the boundary of the first subpixel; first and second light emitting stacks, a charge generation layer, and a second electrode separated by the partitional wall; and an intermediate electrode separated by the partition wall and in the first subpixel, located between the charge generation layer and the second light emitting stack in the first subpixel, and connected to the connection electrode, wherein the second light emitting stack emits a color of the first subpixel, and the first light emitting stack emits a mixed color of colors of the second and third subpixels. The present invention can reduce a power consumption and a material cost of a color filter pattern.

### CROSS-REFERENCE TO RELATED APPLICATION

The present application claims the priority of Korean Patent Application No. 10-2023-0191301 filed on Dec. 26, 2023, which is hereby incorporated by reference in its entirety.

### BACKGROUND

### Field of the Disclosure

The present disclosure relates to a light emitting display device.

### Description of the Background

Recently, flat panel display devices having excellent characteristics such as thinness, light weight, and low power consumption have been widely developed and applied to various fields.

Among the flat panel display devices, a light emitting display device including a light emitting element such as a light emitting diode is a display device in which charges are injected into a light emitting layer formed between an anode and a cathode to form pairs of electrons and holes, and then the pairs disappear to emit light.

Recently, the light emitting element of the light emitting display device are formed in a tandem structure. In this tandem structure, a plurality of light emitting stacks stacked in a vertical direction emit light simultaneously to generate white color.

In this case, since all light emitting stacks provided in a subpixel emit light, there is a problem with high power consumption.

### SUMMARY

The present disclosure is to provide a light emitting display device that reduces power consumption and implement low-power operation when using a light emitting element with a tandem structure.

Additional features and advantages of the disclosure will be set forth in the description which follows, and in part will be apparent from the description, or may be learned by practice of the disclosure. These and other advantages of the disclosure will be realized and attained by the structure particularly pointed out in the written description and claims hereof as well as the appended drawings.

To achieve these and other advantages and in accordance with the purpose of the present disclosure, as embodied and broadly described herein, a light emitting display device includes: a substrate including a display region in which first, second, and third subpixels of different colors are arranged; a first electrode formed in each of the first, second, and third subpixels; a partition wall of an overhang structure which extends along a boundary between the first subpixel and the second and third subpixels, and includes a protrusion portion protruding outward; a connection electrode formed under the protrusion portion of the partition wall at the boundary of the first subpixel; first and second light emitting stacks disposed on the first electrode of the first subpixel and on the first electrodes of the second and third subpixels, a charge generation layer between the first and second light emitting stacks, and a second electrode on the second light emitting stack, wherein the first and second light emitting stacks, the charge generation layer, and the second electrode in the first subpixel are respectively separated from the first and second light emitting stacks, the charge generation layer, and the second electrode in the second subpixel by the partitional wall; and an intermediate electrode which is separated by the partition wall and disposed in the first subpixel, is located between the charge generation layer and the second light emitting stack in the first subpixel, and is connected to the connection electrode, wherein the second light emitting stack emits a color of the first subpixel, and the first light emitting stack emits a mixed color of colors of the second and third subpixels.

In another aspect of the present disclosure, a light emitting display device includes: a substrate including a display region in which a plurality of subpixels are arranged; a first electrode formed for each subpixel; a partition wall which is formed along a boundary of the subpixel, and includes first to third partition walls which are stacked upward, each have an overhang structure, and respectively include first to third protrusion portions protruding outward; a first connection electrode formed below the first protrusion portion, a second connection electrode formed on a top surface of the first protrusion portion, and a third connection electrode formed on a top surface of the second protrusion portion; and first, second, and third light emitting stacks stacked on the first electrode and emitting different colors, a second electrode on the third light emitting stack, a first charge generation layer between the first and second light emitting stacks, a second charge generation layer between the second and third light emitting stacks, a first intermediate electrode between the first charge generation layer and the second light emitting stack, and a second intermediate electrode between the second charge generation layer and the third light emitting stack, wherein the first to third light emitting stacks, the first and second charge generation layers, the first and second intermediate electrodes, and the second electrode are separated for each subpixel by the partitional wall, and wherein the first and second intermediate electrodes and the second electrode are respectively connected to the first, second and third connection electrodes.

A light emitting display device, comprising: a substrate including a display region in which first, second, and third subpixels of different colors are arranged, a first electrode formed in each of the first, second, and third subpixels, a partition wall having an overhang structure which extends along a boundary between the adjacent first subpixel and the adjacent second and third subpixels, and includes a protrusion portion protruding outward towards the adjacent subpixels, a connection electrode formed under the protrusion portion of the partition wall at the boundary of the first subpixel, first and second light emitting stacks disposed on the first electrode of the first subpixel and on the first electrodes of the second and third subpixels, a first charge generation layer disposed between the first and second light emitting stacks, and a second electrode disposed on the second light emitting stack, wherein the first and second light emitting stacks, the first charge generation layer, and the second electrode are separated by the partitional wall, and a first intermediate electrode which is separated by the partition wall and disposed in the first subpixel, is located between the charge generation layer and the second light emitting stack in the first subpixel, and is connected to the connection electrode.

It is to be understood that both the foregoing general description and the following detailed description are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this disclosure, illustrate aspects of the disclosure and together with the description serve to explain the principles of the disclosure.

In the drawings:

FIG. 1 is a plan view schematically illustrating a light emitting display device according to a first aspect of the present disclosure;

FIG. 2 is a cross-sectional view taken along line II-II′ of FIG. 1;

FIG. 3 is a cross-sectional view enlarging region A of FIG. 2;

FIG. 4 is a view schematically illustrating a voltage line to provide a low-potential driving voltage into a display region according to the first aspect of the present disclosure;

FIG. 5 is a cross-sectional view schematically illustrating a light emitting display device according to a second aspect of the present disclosure;

FIG. 6 is a cross-sectional view enlarging region B of FIG. 5;

FIG. 7 is a plan view schematically illustrating a light emitting display device according to a third aspect of the present disclosure;

FIG. 8 is a cross-sectional view taken along line VIII-VIII′ of FIG. 7;

FIG. 9 is a cross-sectional view enlarging region C of FIG. 8; and

FIGS. 10 to 12 are diagrams illustrating examples of various colors that may be implemented in a subpixel using a light emitting diode of a tandem structure according to the third aspect of the present disclosure.

### DETAILED DESCRIPTION

Advantages and features of the present disclosure and methods of achieving them will be apparent with reference to the aspects described below in detail with the accompanying drawings. However, the present disclosure is not limited to the aspects disclosed below, but may be realized in a variety of different forms, and only these aspects allow the present disclosure to be complete. The present disclosure is provided to fully inform the scope of the disclosure to the skilled in the art of the present disclosure, and the present disclosure may be defined by the scope of the claims.

The shapes, sizes, proportions, angles, numbers, and the like disclosed in the drawings for explaining the aspects of the present disclosure are illustrative, and the present disclosure is not limited to the illustrated matters. The same reference numerals refer to the same components throughout the description.

Furthermore, in describing the present disclosure, if it is determined that a detailed description of the related known technology unnecessarily obscure the subject matter of the present disclosure, the detailed description thereof may be omitted. When ‘comprising’, ‘including’, ‘having’, ‘consisting’, and the like are used in this disclosure, other parts may be added unless ‘only’ is used. When a component is expressed in the singular, cases including the plural are included unless specific statement is described.

In interpreting the components, even if there is no separate explicit description, it is interpreted as including a margin range.

In the case of a description of a positional relationship, for example, when the positional relationship of two parts is described as ‘on’, ‘over’, ‘above’, ‘below’, ‘beside’, ‘under’, and the like, one or more other parts may be positioned between such two parts unless ‘right’ or ‘directly’ is used.

In the case of a description of a temporal relationship, for example, when a temporal precedence is described as ‘after’, ‘following’, ‘before’, and the like, cases that are not continuous may be included unless ‘directly’ or ‘immediately’ is used.

In describing components of the present disclosure, terms such as first, second and the like may be used. These terms are only for distinguishing the components from other components, and an essence, order, order, or number of the components is not limited by the terms.

Respective features of various aspects of the present disclosure may be partially or wholly connected to or combined with each other and may be technically interlocked and driven variously, and respective aspects may be independently implemented from each other or may be implemented together with a related relationship.

Hereinafter, aspects of the present disclosure are described in detail with reference to the drawings. Meanwhile, in the following aspects, the same and like reference numerals are assigned to the same and like components, and detailed descriptions thereof may be omitted.

### <First Aspect>

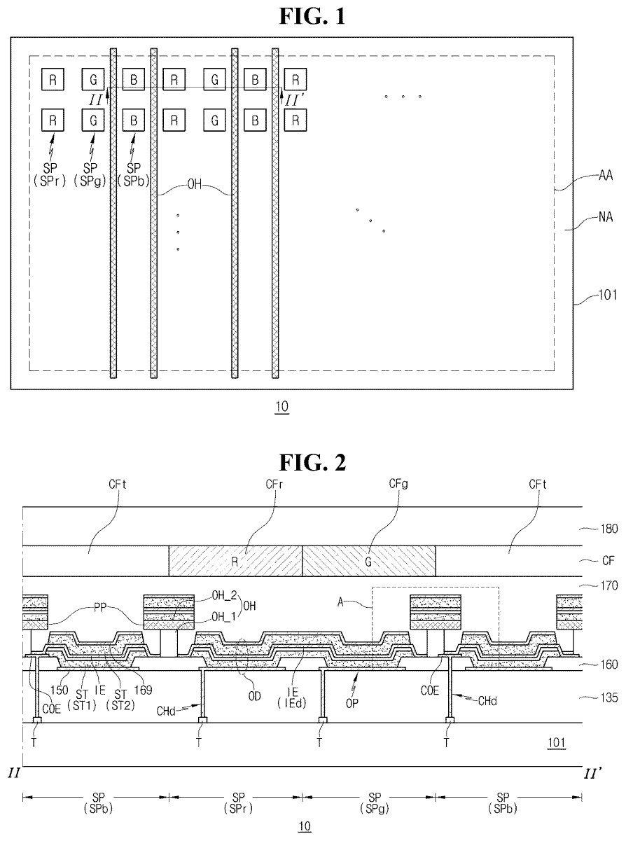

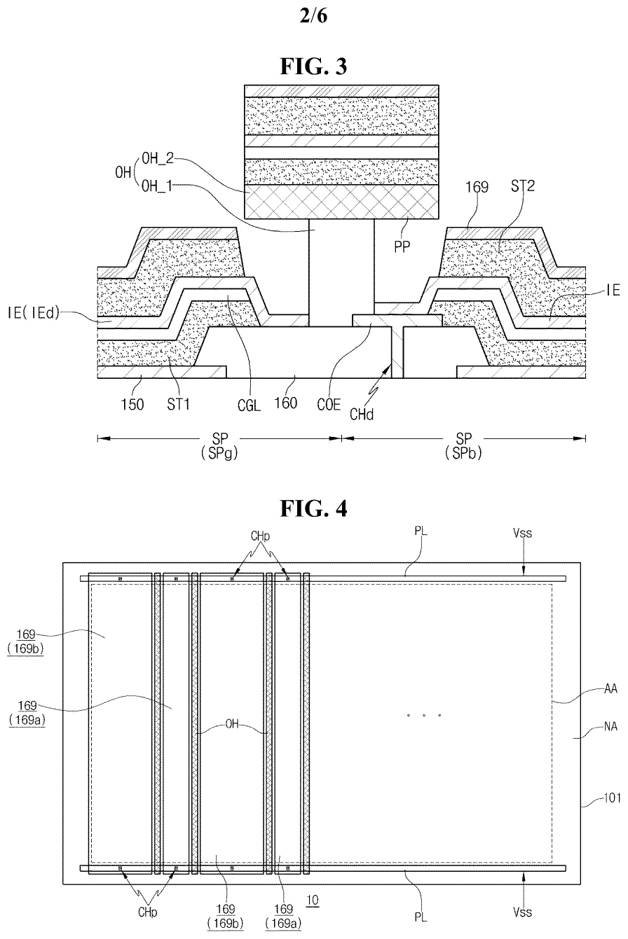

FIG. 1 is a plan view schematically illustrating a light emitting display device according to a first aspect of the present disclosure. FIG. 2 is a cross-sectional view taken along line II-II′ of FIG. 1. FIG. 3 is a cross-sectional view enlarging region A of FIG. 2, showing a partition wall (or separation wall) and its surroundings.

Prior to a detailed description, the light emitting display device 10 according to an aspect of the present disclosure may include all types of display devices that display images with light emitting diodes OD which are self-luminescent elements.

In this aspect, for convenience of explanation, an organic light emitting display device is used as the light emitting display device 10 as an example.

Additionally, the light-emitting display device 10 may be a top emission type display device or a bottom emission display device. In this aspect, for convenience of explanation, the top emission type light emitting display device 10 is taken as an example.

Referring to FIGS. 1 to 3, in the light emitting display device 10 (or its light emitting display panel) of this aspect, a display region AA for displaying an image and a non-display region NA disposed around the display region AA may be defined.

The display area AA may include a plurality of subpixels SP arranged along a plurality of row lines (or horizontal lines) and a plurality of column lines (or vertical lines) on the substrate 101.

Meanwhile, although not specifically shown, a plurality of gate lines (or scan lines) extending along the row direction (or horizontal direction or first direction) and a plurality of data lines extending along the column direction (or vertical direction or second direction) may be formed on the substrate 101. Each subpixel SP may be connected to corresponding gate line and data line. Additionally, a power line that transmits a high-potential driving voltage may be formed on the substrate 101.

The plurality of subpixels SP formed on the substrate 101 may include subpixels SP of different colors constituting a pixel which is a unit for displaying a color image. In this regard, for example, the plurality of subpixels SP constituting the pixel are blue (B), red (R), and green (G) subpixels (or first, second, and third subpixels) SPb, SPr, and SPg which respectively display first, second, and third colors, for example, blue (B), red (R), and green (G). As another example, the plurality of subpixels SP constituting the pixel may further include a white (W) subpixel that displays white light.

In this aspect, a case where the pixel is configured with the R, G, and B subpixels SPr, SPg, and SPb is taken as an example.

The R, G, and B subpixels SPr, SPg, and SPb may be arranged in various shapes. For example, as shown in FIG. 1, the R, G, and B subpixels SPr, SPg, and SPb may be arranged in a stripe type in which the subpixels SP of the same color are arranged along the column direction and the subpixels SP of different colors are alternately arranged along the row direction, but not limited thereto.

Each subpixel SP may be provided with, for example, a light emitting diode OD capable of generating white light.

In this aspect, the light emitting diode OD may be configured in a tandem structure. In this regard, the light emitting diode OD may include a plurality of light emitting stacks (or light emitting units) (ST: ST1 and ST2) that may emit two or more different colors that realize white when mixed.

In this aspect, for convenience of explanation, a case in which first and second light emitting stacks ST1 and ST2 which are two light emitting stacks are formed in the light emitting diode OD, the first and second light emitting stacks ST1 and ST2 emit different colors, and white may be generated when the colors emitted from the first and second light emitting stacks ST1 and ST2 are mixed is taken as an example. In this regard, a case in which the first light emitting stack ST1 emits yellow which is a mixed color of red and green, and the second light emitting stack ST2 emits blue is taken as an example.

Additionally, the light emitting diode OD may include a charge generation layer CGL disposed between neighboring light emitting stacks ST. The charge generation layer CGL functions to lower a Fermi barrier so that electrons and holes may easily move between the neighboring light emitting stacks ST.

Meanwhile, the light emitting diode OD may include an intermediate electrode IE disposed between the first and second light emitting stacks ST1 and. As such, when the intermediate electrode IE is formed between the light emitting stacks ST1 and ST2 constituting the light emitting diode OD, it is possible to apply an individual light emission current (or driving current) to the intermediate electrode IE. In other words, a light emission current (or second light emission current) independent of a light emission current (or first light emission current) applied to an anode 150 may be applied to the intermediate electrode IE.

As such, when a separate light emission current is applied to the intermediate electrode IE, the second light emitting stack ST2 that is the light emitting stack ST of the light emitting diode OD through which the light emission current flows may individually perform a light emission operation.

In this regard, for example, the first and second light emitting stacks ST1 and ST2 may perform a light emission operation together by a light emission current applied to the anode 150, and the second light emitting stack ST2 may perform a light emission operation by a light emission current applied to the intermediate electrode IE which serves as an anode of the second light emitting stack ST2.

In this aspect, for some subpixels SP, a light emission current may be applied to the intermediate electrode IE of the light emitting diode OD, and a light emission current may not be applied to the anode 150 of the light emitting diode OD. In addition, for other subpixels SP, a light emission current may not be applied to the intermediate electrode IE of the light emitting diode OD, and a light emission current may be applied to the anode 150 of the light emitting diode OD.

In this case, in the subpixel SP where a light emission current is applied to the intermediate electrode IE, the second light emission stack ST2 to which the light emission current is applied among the first and second light emission stacks ST1 and ST2 is driven and thus performs a light emitting operation, and the first light emission stack ST1 is not driven and thus does not perform a light emission operation (i.e., is in a light emission off state). As such, as the second light emitting stack ST2 independently performs a light emission operation, the light emitting diode OD of the subpixel SP substantially generates blue light.

In addition, in the subpixel SP where a light emission current is not applied to the intermediate electrode IE and is applied to the anode 150, the first and second light emitting stacks ST1 and ST2 are all driven to perform a light emission operation. As such, as the first and second light emitting stacks ST1 and ST2 perform a light emission operation together, the light emitting diode OD of the subpixel SP substantially generates white light.

In this regard, in this aspect, the B subpixel SPb displaying blue is configured such that a light emission current is to be applied to the intermediate electrode IE, and the R and G subpixels SPr and SPg are configured such that no separate light emission current is applied to the intermediate electrodes (IE: IEd). Here, the intermediate electrodes IE of the R and G subpixels SPr and SPg to which no separate light emission current is applied substantially function as (or are referred to as) dummy intermediate electrode IEd. In other embodiments the intermediate electrode of the R and/or G subpixels may be an active intermediate electrode and the intermediate electrode of the B subpixel may be a dummy intermediate electrode.

In this case, the intermediate electrode IE of the B subpixel SPb to which a light emission current is applied and the dummy intermediate electrodes IEd of the R and G subpixels SPr and SPg to which a light emission current is not applied may be physically separated from each other and have a disconnected form.

The disconnected structure of the intermediate electrode IE and the dummy intermediate electrode IEd may be implemented, for example, through a partition wall OH which has an overhang-shaped structure.

For example, the partition wall OH having the overhang structure may be disposed along a boundary between the B subpixel SPb in which the intermediate electrode IE is formed and the R and G subpixels SPr and SPg adjacent to the B subpixel SPb. Accordingly, the intermediate electrode IE is formed in the B subpixel SPb and the dummy intermediate electrodes IEd are formed in the R and G subpixels SPr and SPg, so that the intermediate electrode IE and the dummy intermediate electrodes IEd may be physically separated from each other and be in a disconnected state.

The separation structure of the intermediate electrode IE by the partition wall OH of the overhang structure may be similarly applied to the first and second light emitting stacks ST1 and ST2 and the charge generation layer CGL. Accordingly, the first and second light emitting stacks ST1 and ST2 and the charge generation layer CGL may be physically separated and disconnected between the B subpixel SPb and its neighboring R and G subpixels SPr and SPg.

Likewise, the cathode 169 forming the light emitting diode OD may also be physically separated and disconnected between the B subpixel SPb and its neighboring R and G subpixels SPr and SPg by the partition wall OH of the overhang structure.

As such, in this aspect, when using the light emitting diode OD of the tandem structure capable of emitting white light, in the B subpixel SPb, the second light emitting stack ST2 emitting blue that is the color of the B subpixel SPb is individually driven, and the first light emitting stack ST1 of different color placed below the second light emitting stack ST2 is not driven. In addition, in the R and G subpixels SPr and SPg, the first light emitting stack ST1 emitting yellow that is a relevant color of the R and G subpixels SPr and SPg, and the second light emitting stack ST2 emitting blue and disposed on the first light emitting stack ST1 may be driven simultaneously.

As such, the B subpixel SPb is sufficient to drive the second light emitting stack ST2 representing the color of the B subpixel SPb and does not drive the first light emitting stack ST1, so that power consumption may be reduced.

In addition, the B subpixel SPb may express blue by driving the second light emitting stack ST2 producing blue, so that there is no need to form a blue color filter pattern in the B subpixel SPb. Thus, a material cost of a color filter pattern may be reduced.

The planar and cross-sectional structures of the subpixels SP of this aspect are described in more detail below.

Referring to FIGS. 2 and 3 along with FIG. 1, in each subpixel SP, a subpixel driving circuit including a thin film transistor T, and the light emitting diode OD may be formed on the substrate 101. Meanwhile, although not specifically shown, in the subpixel driving circuit of the subpixel SP, a plurality of thin film transistors including the thin film transistor T as shown may be formed, and at least one capacitor may be formed.

In more detail, the thin film transistor T may be formed in each subpixel SP on the substrate 101. For example, the thin film transistor T may be connected to the light emitting diode OD to provide a light emitting current.

In this regard, in the B subpixel SPb as the subpixel (SP) to which a light emitting current is applied to the intermediate electrode IE, a light emission current may be applied to the intermediate electrode IE through the thin film transistor T. In addition, since a light emission current is not directly provided to the anode 150 of the B subpixel SPb, a thin film transistor that is connected to the anode 150 to provide a light emission current is not provided in the B subpixel SPb.

Meanwhile, in each of the R and G subpixels SPr and SPg as the subpixels SP provided with the dummy intermediate electrodes IEd that are the intermediate electrodes IE to which no separate light emission current is applied, a light emission current may be applied to the anode 150 through the thin film transistor. In addition, since a light emission current is not directly provided to the dummy intermediate electrodes IEd of the R and G subpixels SPr and SPg, a thin film transistor that is connected to the dummy intermediate electrode IEd to provide a light emission current is not provided in each of the R and G subpixels SPr and SPg.

Although not specifically shown for convenience of explanation, the thin film transistor T disposed in each subpixel SP may include a gate electrode, a source electrode, a drain electrode, and a semiconductor layer.

Here, the semiconductor layer of the thin film transistor T may be formed of, for example, amorphous silicon, polycrystalline silicon, or an oxide semiconductor material, but not limited thereto.

In addition, the thin film transistor may be configured in a coplanar structure (or top gate structure) in which the gate electrode is located on a semiconductor layer and the source and drain electrodes are disposed on the gate electrode, or be configured in an inverted staggered structure (or bottom gate structure) in which the semiconductor layer is located on the gate electrode and the source electrode and the drain electrode are disposed on the semiconductor layer.

Meanwhile, a buffer layer formed of an insulating material may be formed between the thin film transistor T and the substrate 101.

A passivation layer 135 may be formed on the thin film transistor T and be an insulating layer formed of an insulating material.

The passivation layer 135 may be formed of at least one of an inorganic insulating material such as silicon oxide or silicon nitride, and an organic insulating material such as benzocyclobutene or photoacrylic, but not limited thereto. The passivation layer 135 may be formed in a single-layered structure or multi-layered structure.

A drain contact hole CHd exposing the drain electrode of the thin film transistor T may be formed in the passivation layer 135.

The anode (or first electrode) 150 may be formed on the passivation layer 135 for each subpixel SP (or in a unit of each subpixel SP).

In this regard, the anode 150 of the subpixel SP may be substantially integrally formed within the subpixel SP, and may be formed in a continuous form within the subpixel SP. The anode 150 may be physically separated from and spaced apart from the anode 150 of the neighboring subpixel SP.

The anode 150 disposed in each of the R and G subpixels SPr and SPg may contact the drain electrode of the thin film transistor T through the drain contact hole CHd.

When the light emitting display device 10 is a top emission type, the anode 150 may include an opaque metal material and may have high reflection characteristics. For example, the anode 150 may include one of Ag, Al, Mo, Ti, and APC (Al—Pd—Cu) alloy, but not limited thereto.

Meanwhile, the anode 150 may be formed in a multi-layered structure. In this regard, for example, it may be formed as a multi-layer structure in which a transparent conductive material (e.g., ITO, IZO, IZTO, or the like) is laminated on and/or below the above opaque metal material.

As another example, when the light emitting display device 10 is a bottom emission type, the anode 150 may include a transparent electrode layer and may not include a reflective layer.

A bank 160 may be formed on the anode 150 and the passivation layer 135 along a boundary of each subpixel SP (or a boundary between neighboring subpixels SP).

The bank 160 may be formed to cover an edge of the anode 150 disposed in each subpixel SP.

The bank 160 may be formed of, for example, at least one of acrylic resin, epoxy resin, phenolic resin, polyamide-based resin, polyimide-based resin, unsaturated polyester-based resin, polyphenylene-based resin, polyphenylene sulfide-based resin, benzocyclobutene and photoresist, but not limited thereto.

The bank 160 may be formed to substantially surround the subpixel SP along a periphery of each subpixel SP and may have an opening OP therein. Through the opening OP, the anode 150 of each subpixel SP may be exposed upwardly.

The partition wall OH of the overhang structure may be formed on the bank 160. The partition wall OH may function to separate elements constituting the light emitting diode OD.

Regarding the arrangement of the partition wall OH, for example, the partition wall OH of the overhang structure may be formed on the bank 160 located between the B subpixel SPb that is the subpixel SP in which the intermediate electrode IE is formed and the R and G subpixels SPr and SPg which are adjacent to the B subpixel SPb and in which the dummy intermediate electrodes IEd are formed.

For example, the partition wall OH may be configured to include a first part OH_1, and a second part OH_2 that is located on the first part OH_1 and has a larger size (or larger width or larger area) than the first part OH_1 to implement the overhang structure.

As such, the first part OH_1 located below has a relatively narrow width, and the second part OH_2 located on the first part OH_1 has a relatively wide width, so that the second part OH_2 has the overhang shape that protrudes in both directions beyond the first part OH_1. Thus, the partition wall OH, which is a structure formed by a combination of the first and second parts OH_1 and OH_2, may be formed as an overhang structure. Accordingly, the second part OH_2 may have a protrusion portion (or overhang portion) PP which is a portion that protrudes outward from the first part OH_1.

The partition wall OH may be formed to extend along, for example, the column direction, as shown in FIG. 1.

In this regard, the partition walls OH may be located at both boundaries of the B subpixel SPb and extend along the column direction, so that the partition wall OH may physically separate a column line region where the B subpixels SPb are arranged from a column line region where the R and G subpixels SPb and SPg are arranged.

In other words, in a region between two neighboring partition walls OH located on both sides of the B subpixel SPb, the B subpixels SPb may be located and arranged in one column line. That is, in a region between two neighboring partition walls OH located on both sides of a combination of the R and G subpixels SPr and SPg, the combination of the R and G subpixels SPr and SPg may be located and arranged in one column line.

As described above, in this aspect, the partition walls OH of the overhang structure may be formed to extend in the column direction along both boundaries of the B subpixel SPb where the intermediate electrode IE is formed. Additionally, the partition wall OH may not be formed along the boundary between the R and G subpixels SPr and SPg.

Meanwhile, a connection electrode COE connected to the drain electrode of the thin film transistor T may be formed on the bank 160 located at the boundary of the B subpixel SPb.

In this regard, for example, the connection electrode COE may be formed on a top surface (or upper surface) of the bank 160 and may have a shape extending toward an inside of the B subpixel SPb. An outer part of the connection electrode COE may be positioned to be covered with the partition wall OH (more specifically, be covered with the first part OH_1).

In other words, the first part OH_1 of the partition wall OH may cover the outer part of the connection electrode COE, and the remaining part of the connection electrode COE may not be covered by the first part OH_1 but may be located under the protrusion portion PP of the second part OH_2 to have a substantially exposed state.

Meanwhile, in the B subpixel SPb, the drain contact hole CHd may be formed in a portion of the bank 160 where the connection electrode COE is formed. As such, in the B subpixel SPb, the drain contact hole CHd may be formed in the passivation layer 135 and the bank 160.

Accordingly, the connection electrode COE may contact the drain electrode of the corresponding thin film transistor T through the drain contact hole CHd.

A plurality of stacked films may be deposited on the substrate 101 having the partition wall OH and the connection electrode COE to form the light emitting diode OD, so that the light emitting diode OD of the tandem structure may be formed in the subpixel SP.

In this regard, for example, the light emitting diode OD may include the first and second light emitting stacks ST1 and ST2 stacked upward, the cathode (or second electrode) 169 stacked on the second light emitting stack ST2, and the charge generation layer CGL stacked between the first and second light emitting stacks ST1 and ST2. Additionally, the intermediate electrode IE may be formed between the charge generation layer CGL and the second light emitting stack ST2.

The stacked films constituting the light emitting diode OD may be formed in a structure separated by the partition wall OH.

In this regard, the first light emitting stacks ST1 emitting yellow may be separated with the partition wall OH therebetween. Accordingly, the first light emitting stack ST1 may be formed on the anode 150 and the bank 160 of the B subpixel SPb. In addition, another first light emitting stack ST1, which is separated from the first light emitting stack ST1 of the B subpixel SPb by the partition wall OH, may be formed in an integrated (or continuous) form on the anode 150 and the bank 160 of the R and G subpixels SPr and SPg.

The first light emitting stack ST1 may include a plurality of organic stacked films to perform a light emission function. For example, the first light emitting stack ST1 may include a hole injection layer, a hole transport layer, an emission material layer, an electron transport layer, etc., but not limited thereto.

Here, the first light emitting stack ST1 formed in the B subpixel SPb may be formed to expose at least a portion of the connection electrode COE located below the partition wall OH (more specifically, located below the protrusion portion PP). In this aspect, a case where the first light emitting stack ST1 is formed to cover an end of the connection electrode COE is taken as an example.

Accordingly, when the first light emitting stack ST1 is formed by deposition, the connection electrode COE may be exposed between the first light emitting stack ST1 and the partition wall OH.

The charge generation layer CGL formed on the first light emitting stack ST1 may also be formed in substantially the same shape as the first light emitting stack ST1.

In this regard, the charge generation layer CGL may be separated by the partition wall OH, so that the charge generation layer CGL may be formed in the B subpixel SPb, and may be integrally formed in the R and G subpixels SPr and SPg. Additionally, the charge generation layer CGL formed in the B subpixel SPb may be formed to expose at least a portion of the connection electrode COE located below the partition wall OH, and may be formed to cover an end of the connection electrode COE, similar to the first light emitting stack ST1.

The intermediate electrode IE formed on the charge generation layer CGL may be formed to be separated by the partition wall OH, similar to the first light emitting stack ST1 and the charge generation layer CGL.

In this regard, the intermediate electrode IE may be formed on the charge generation layer CGL of the B subpixel SPb, and the dummy intermediate electrode IEd may be formed on the charge generation layer CGL of the R and G subpixels SPb. The intermediate electrode IE and the dummy intermediate electrode IEd may be separated from each other by the partition wall OH.

Here, the intermediate electrode IE of the B subpixel SPb is formed to extend over the connection electrode COE and may contact the exposed connection electrode COE. Accordingly, in the B subpixel SPb, the intermediate electrode IE may be electrically connected to the thin film transistor T via the connection electrode COE. Accordingly, a light emission current flowing through the thin film transistor T may be applied to the connection electrode COE.

In addition, the dummy intermediate electrode IEd disposed in the R and G subpixels SPr and SPg is configured not to receive a separate light emission current. The dummy intermediate electrode IEd is interposed between the first and second light emitting stacks ST1 and ST2 and substantially functions as a conductive layer through which electrons and holes pass.

Meanwhile, in this aspect, in forming the intermediate electrode IE and the dummy intermediate electrode IEd, a deposition angle when depositing a metal material forming the intermediate electrode IE and the dummy intermediate electrode IEd may be set to be smaller than a deposition angle of materials forming the first light emitting stack ST1 and the charge generation layer CGL disposed below the intermediate electrode IE and the dummy intermediate electrode IEd. Here, the deposition angle is an angle based on the surface of the substrate 101.

In this case, the intermediate electrode IE and the dummy intermediate electrode IEd may be formed to have a larger area than the stacked films located below them.

Accordingly, the intermediate electrode IE and the dummy intermediate electrode IEd are formed to have a size (or width) larger than those of the first light emitting stack ST1 and the charge generation layer CGL. Thus, the intermediate electrode IE and the dummy intermediate electrode IEd may have a shape extending outward (towards the partition wall OH) while substantially covering the first light emitting stack ST1 and the charge generation layer CGL.

As a result, the intermediate electrode IE disposed in the B subpixel SPb may contact the connection electrode COE exposed to an outside of the first light emitting stack ST1 and contact the charge generation layer CGL. Thus, the intermediate electrode IE may receive a light emission current that may drive the second light emitting stack ST2 of the B subpixel SPb.

The second light emitting stack ST2, which is formed on the intermediate electrode IE and the dummy intermediate electrode IEd and emits blue, may be formed to be separated by the partition wall OH, similar to the first light emitting stack ST1 and the charge generation layer CGL.

In this regard, the second light emitting stack ST2 may be formed on the intermediate electrode IE of the B subpixel SPb. In addition, another second light emitting stack ST2, which is separated from the second light emitting stack ST2 of the B subpixel SPb by the partition wall OH, may be formed in an integrated form on the dummy intermediate electrode IEd of the R and G subpixels SPr and SPg.

The second light emitting stack ST2 may include a plurality of organic stacked films to perform a light emission function. For example, similar to the first light emitting stack ST1, the second light emitting stack ST2 may include a hole injection layer, a hole transport layer, an emission material layer, an electron transport layer, etc., but not limited thereto.

Here, the second light emitting stack ST2 formed in the B subpixel SPb may be formed with a smaller area than the intermediate electrode IE located therebelow. As another example, the second light emitting stack ST2 formed in the B subpixel SPb may be formed with a larger area than the intermediate electrode IE to cover the intermediate electrode IE.

Additionally, the second light emitting stack ST2 formed in the R and G subpixels SPr and SPg may be formed with a smaller area than the dummy intermediate electrode IEd located therebelow. As another example, the second light emitting stack ST2 formed in the R and G subpixels SPr and SPg may be formed with a larger area than the dummy intermediate electrode IEd to cover the dummy intermediate electrode IEd.

A size of the second light emitting stack ST2 on the intermediate electrode IE and the dummy intermediate electrode IEd may be adjusted depending on a deposition angle of the second light emitting stack ST2.

The cathode 169 formed on the second light emitting stack ST2 may be formed in a similar shape to the second light emitting stack ST1.

In this regard, the cathode 169 may be separated by the partition wall OH, so that the cathode 169 may be formed in the B subpixel SPb and be integrally formed in the R and G subpixels SPr and SPg.

Here, in terms of preventing a short circuit (or contact) between the cathode 169 and the intermediate electrode IE in the B subpixel SPb, and a short circuit (or contact) between the cathode 169 and the dummy intermediate electrode IEd in the R and G subpixels SPr and SPg, a size (or width) of the cathode 169 may be formed to be equal to or less than that of the second light emitting stack ST2 therebelow.

Meanwhile, the cathode 169 may have a shape extending along the column direction that is the direction in which the partition wall OH extends. In this case, the cathode 169 may further extend to the non-display region NA and be connected to a voltage line disposed in the non-display region NA to receive a low-potential driving voltage. This refers to FIG. 4.

FIG. 4 is a view schematically illustrating a voltage line to provide a low-potential driving voltage into a display region according to the first aspect of the present disclosure.

Referring to FIG. 4, the voltage line PL may be disposed on both sides of the display region AA, for example, in upper and lower non-display regions NA in FIG. 4. The voltage wiring PL may directly receive the low-potential driving voltage Vss output from an external power circuit (not shown).

In this case, the cathode (169:169a) extending in the column direction along the B subpixel SPb and the cathode (169:169b) extending in the column direction along the R and G subpixels SPr and SPb may cross the display region AA. One end of each of the cathode (169:169a) and the cathode (169:169b) may be connected to the voltage line PL placed in the upper non-display region NA through a contact hole CHp, and the other end of each of the cathode (169:169a) and the cathode (169:169b) may be connected to the voltage line PL placed in the lower non-display region NA through the contact hole CHp.

Accordingly, the low-potential driving voltage Vss may be applied to each of the cathode 169a corresponding to the B subpixel SPb and the cathode 169b corresponding to the R and G subpixels SPr and SPg.

When the light emitting display device 10 is a top emission type, the cathode 169 may include a transparent electrode layer formed of a transparent conductive material (e.g., ITO, IZO, IZTO, etc.). As another example, when the light emitting display device 10 is a bottom emission type, the cathode 169 may include a reflective layer formed of metal.

As above, by using the partition wall OH, the first light emitting stack ST1, the charge generation layer CGL, the intermediate electrode IE, the second light emitting stack ST2, and the cathode 169 may be separated.

Accordingly, in the B subpixel SPb, the yellow first light emitting stack ST1, the charge generation layer CGL, the intermediate electrode IE, the blue second light emitting stack ST2, and a cathode 169, which are stacked in a pattern by the partition wall OH on the anode 150, may be formed, and the intermediate electrode IE may be in contact with the connection electrode COE and receive a light emission current, which drives the second light emitting stack ST2, from the corresponding thin film transistor T. Accordingly, the light emission current flows through the second light emitting stack ST2, allowing the light emitting diode OD to emit and output blue light.

In the R and G subpixels SPr and SPg, the yellow first light emitting stack ST1, the charge generation layer CGL, and the dummy intermediate electrode IEd, the blue second light emitting stack ST2, and a cathode 169, which are stacked in a pattern by the partition wall OH on the anode 150, may be formed, and the anode 150 of each of the R and G subpixels SPr and SPg may be connected to the corresponding thin film transistor T and receive a light emission current which drives the first and second light emitting stacks ST1 and ST2 together. Accordingly, the light emission current flows through the first and second light emitting stacks ST1 and ST2, allowing the light emitting diode OD to emit and output white light which is a mixture of yellow light and blue light.

As such, in this aspect, the B subpixel SPb may emit blue light by individually driving the second light emitting stack ST2 of the blue which the B subpixel SPb wishes to express, and each of the R and G subpixels SPr and SPg may emit white light by driving the yellow first light emitting stack ST1 and the blue second light emitting stack ST2 together.

Meanwhile, as mentioned above, the intermediate electrode IE patterned by the partition wall OH may be continuously formed along the B subpixels SPb arranged in the same column line. In this case, between neighboring B subpixels (SPb) along the column line, a leakage current through the intermediate electrode IE is small enough to be practically negligible. Therefore, crosstalk due to a leakage current between neighboring B subpixels SPb is not realistically recognized, and image distortion due to a leakage current is not caused.

An encapsulation layer 170 may be formed substantially over the entire surface of the substrate 101 having the cathode 169 separated by the partition wall OH of the overhang structure.

The encapsulation layer 170 may serve to improve reliability by blocking penetration of moisture or oxygen from an outside.

Moreover, the encapsulation layer 170 may planarize the substrate 101 having the cathode 169.

The encapsulation layer 170 may be formed in a single-layered structure or multi-layered structure using at least one of an inorganic insulating material and an organic insulating material.

A color filter layer CF may be formed on the encapsulation layer 170. The color filter layer CF may include red and green color filter patterns CFr and CFg which are located corresponding to the R and G subpixels SPr and SPg and generate red and green, respectively.

Moreover, the color filter layer CF may include a transparent pattern CFt with transparent characteristics which is located corresponding to the B subpixel SPb.

In this regard, as mentioned above, the light emitting diode OD of each of the R and G subpixels SPr and SPg emits white light which is a mixed color by the light emission operation of the first and second light emitting stacks ST1 and ST2. Thus, the red and green color filter patterns CFr and CFg may be respectively disposed in the R and G subpixels SPr and SPg to express red and green which are the colors of the R and G subpixels SPr and SPg.

Meanwhile, the light emitting diode OD of the B subpixel SPb emits blue because the yellow first light emitting stack ST1 turns off its light emission operation and the blue second light emitting stack ST2 turns on its light emission operation. Thus, there is no need to place a blue color filter pattern in the B subpixel SPb to express the color of the B subpixel SPb.

Accordingly, the transparent pattern CFt with transparent characteristics that may directly transmit blue emitted from the light emitting diode OD may be disposed for the B subpixel SPb.

As such, for the B subpixel SPb, by forming the transparent pattern CFt without forming a corresponding color filter pattern, a cost for a color filter pattern material may be reduced.

In addition, as mentioned above, in the B subpixel SPb, among the light emitting stacks ST1 and ST2 constituting the light emitting diode OD, the second light emitting stack ST2 that emits the color corresponding to the B subpixel SPb is individually driven and the first light emitting stack ST1 of different color is not driven, so that power consumption may be reduced.

Meanwhile, an overcoat layer 180 may be formed on the color filter layer CF to cover and protect the color filter layer CF. The substrate 101 having the overcoat film 180 may have a substantially flat surface.

### <Second Aspect>

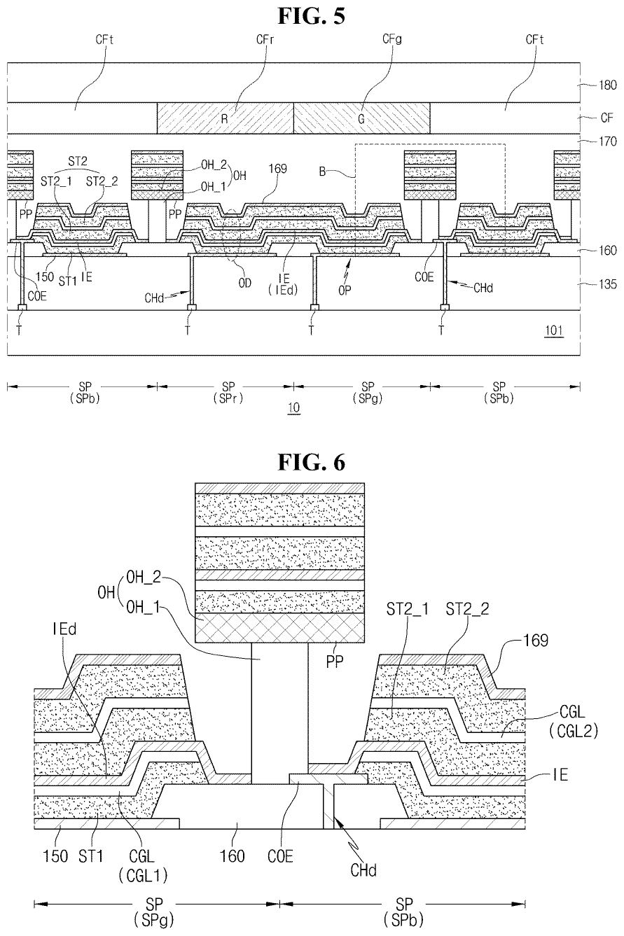

FIG. 5 is a cross-sectional view schematically illustrating a light emitting display device according to a second aspect of the present disclosure. FIG. 6 is a cross-sectional view enlarging a region B of FIG. 5, showing a partition wall and its surroundings.

In the following description, detailed explanations of configurations identical to or similar to those of the above-described first aspect may be omitted.

Referring to FIGS. 5 and 6, similar to the first aspect, the light emitting display device 10 of this aspect includes a light emitting diode OD of a tandem structure, and two light emitting stacks ST1 and ST2 constituting the light emitting diode OD may be separated by partition walls OH disposed along both boundaries of the B subpixel SPb.

In the separation structure, for the B subpixel SPb, a light emission current is applied to an intermediate electrode IE and a light emission current is turned off to an anode 150. Thus, the second light emitting stack ST2 emitting blue that is the color of the B subpixel SPb is individually driven, and the first light emitting stack ST1 of a different color disposed below the second light emitting stack ST2 is not driven (i.e., is in a light emission off state). In addition, for the R and G subpixels SPr and SPg, a light emission current is applied to the anode 150 and a light emission current is turned off to a dummy intermediate electrode IEd. Thus, the first light emitting stack ST1 emitting yellow that is a related color of the R and G subpixels SPr and SPg, and the second light emitting stack ST2 emitting blue and disposed on the first light emitting stack ST2 may be driven simultaneously.

Meanwhile, in this aspect, to improve a blue emission characteristics of the light emitting diode OD, a plurality of second light emitting stacks ST2 emitting blue may be stacked. In this aspect, for convenience of explanation, a case in which two second light emitting stacks (ST2: ST2_1 and ST2_2) are stacked is taken as an example. The second light emitting stack ST2 located lower may be referred to as a second, first (or 2-1) light emitting stack ST2_1, and the second light emitting stack ST2 located upper may be referred to as a second, second (or 2-2) light emitting stack ST2_2.

In this regard, an emission material layer that emits blue has low lifespan and efficiency. To improve this, in this aspect, by disposing the plurality of second light emitting stacks ST2 in the light emitting diode OD of the tandem structure, lifespan and efficiency of blue may be improved.

The second, first (ST2_1) and second, second (ST2_2) light emitting stacks stacked up and down may be separated by the partition wall OH of the overhang structure and may be divided into the B subpixel SPb and the R and G subpixel SPr and SPg. The light emitting stacks ST2_1 and ST2_2 may have substantially the same planar and cross-sectional shape.

Between the light emitting stacks ST2_1 and ST2_2, a charge generation layer (or second charge generation layer) (CGL: CGL2) having a structure separated by the partition wall OH may be disposed.

Meanwhile, as in the first aspect, a charge generation layer (or first charge generation layer) (CGL: CGL1) and intermediate electrode IE, which each have a structure separated by the partitional wall OH, may be placed between the first light emitting stack ST1 and the second, first light emitting stack ST2_1.

Here, in the B subpixel SPb, the intermediate electrode IE may be formed to contact a connection electrode COE. In the R and G subpixels SPr and SPg, the dummy intermediate electrode IEd separated from the intermediate electrode IE may be disposed.

In addition, a cathode 169 having a structure separated by the partition wall OH may be formed on the second, second light emitting stack ST2_2.

An encapsulation layer 170 may be formed on the cathode 169, and a color filter layer CF may be formed on the encapsulation layer 170.

Similar to the first aspect, the color filter layer CF may include red and green color filter patterns CFr and CFg located respectively corresponding to the R and G subpixels SPr and SPg, and a transparent pattern CFt located corresponding to the B subpixel SPb.

As above, in this aspect, the plurality of second light emitting stacks ST2 that emit blue may be stacked in the light emitting diode OD of the tandem structure. Accordingly, blue lifespan and efficiency may increase, and thus blue emission characteristics of the light emitting diode OD may be improved.

### <Third Aspect>

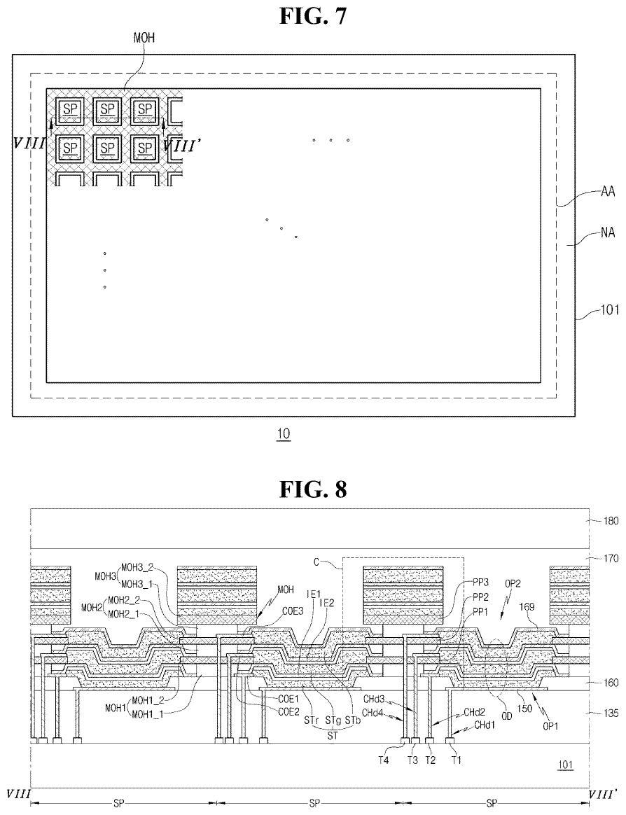

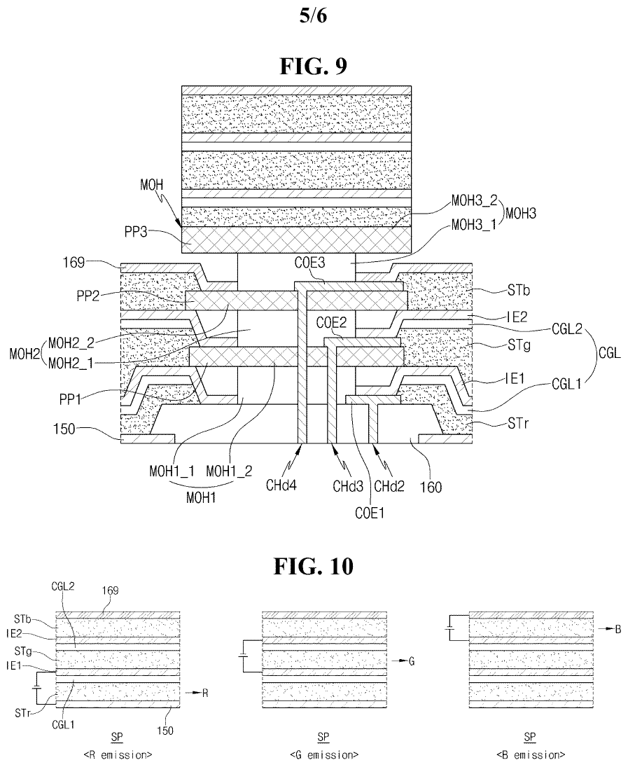

FIG. 7 is a plan view schematically illustrating a light emitting display device according to a third aspect of the present disclosure. FIG. 8 is a cross-sectional view taken along line VIII-VIII′ of FIG. 7. FIG. 9 is a cross-sectional view enlarging region C of FIG. 8.

In the following description, detailed explanations of configurations identical to or similar to those of the above-described first or second aspect may be omitted.

Referring to FIGS. 7 to 9, unlike the first or second aspect, the light emitting display device 10 of this aspect may be configured such that a plurality of light emitting stacks ST constituting a light emitting diode OD of a tandem structure formed in each subpixel SP may be individually driven and driven in combination.

In this regard, the light emitting diode OD of the tandem structure provided in each subpixel SP may include three or more light emitting stacks (ST: STr, STg, and STb) that are sequentially stacked in a vertical direction, may be individually driven, and emit different colors.

In this aspect, for convenience of explanation, a case where the light emitting diode OD of each subpixel SP is configured with three light emitting stacks ST, for example, R, G, and B light emitting stacks (or first, second, and third light emitting stacks) STr, STg, and STb which respectively emit red, green, and blue is taken as an example. In addition, a case where the R, G, and B light emitting stacks STr, STg, and STb are stacked upward in that order is taken as an example. Meanwhile, the stacking order of the R, G, and B light emitting stacks STr, STg, and STb may be changed depending on the case (or need).

Each of the R, G, and B light emitting stacks STr, STg, and STb may receive a light emission current and emit light individually (or emit light singly). Moreover, a light emission current may be applied to two or more adjacent light emitting stacks ST among the R, G, and B light emitting stacks STr, STg, and STb, so that a combined (or mixed) emission may be conducted.

As such, the R, G, and B light emitting stacks STr, STg, and STb that forms the light emitting diode OD of each subpixel SP may emit light individually or in combination, so that each subpixel SP may emit individual color of each light emitting stack ST and mixed color of the combined light emitting stacks ST.

Accordingly, each subpixel SP is not limited to a specific color emission region but may function as a region capable of emitting various colors as needed, thereby maximizing color image expression performance of the light emitting display device 10.

In addition, since the light emission stacks ST of each subpixel SP are capable of both individual emission and combined emission, power consumption is reduced and low-power driving is possible.

In addition, since there is no need to form a specific color filter pattern in every subpixel SP, there is no need to form a color filter layer, and a cost of a color filter pattern material may be reduced to the maximum.

The planar and cross-sectional structures of the subpixel SP of this aspect are described in more detail below.

Referring to FIGS. 8 and 9 along with FIG. 7, in each subpixel SP, a subpixel driving circuit including thin film transistors T1 to T4, and a light emitting diode OD may be formed on the substrate 101. Meanwhile, although not specifically shown, in the subpixel driving circuit of each subpixel SP, a plurality of thin film transistors including the thin film transistors T1 to T4 as shown may be formed, and at least one capacitor may be formed.

In more detail, the plurality of thin film transistors T1 to T4, for example, first to fourth thin film transistors T1 to T4 may be formed in each subpixel SP on the substrate 101.

In this regard, for example, the first thin film transistor T1 may be connected to an anode 150 of the light emitting diode OD to provide a corresponding light emission current. Additionally, the second thin film transistor T2 may be connected to a first intermediate electrode IE1 of the light emitting diode OD to provide a corresponding light emission current. Additionally, the third thin film transistor T3 may be connected to a second intermediate electrode IE2 of the light emitting diode OD to provide a corresponding light emission current. Moreover, the fourth thin film transistor T4 may be connected to a cathode 169 of the light emitting diode OD to provide a corresponding low-potential driving voltage.

By controlling connection states (i.e., connection on/off states) between the first to fourth thin film transistors T1 to T4 and the corresponding electrodes, driving modes (e. g., individual driving, combined driving, etc.) of the first to third light emitting stacks ST1 to ST3 may be adjusted.

For example, when the first and second thin film transistors T1 and T2 are turned on (and the third and fourth thin film transistors T3 and T4 are turned off), a light emission current path is generated between the anode 150 and the first intermediate electrode IE1, so that the R light emitting stack STr between the anode 150 and the first intermediate electrode IE1 may emit light. Additionally, when the second and third thin film transistors T2 and T3 are turned on (and the first and fourth thin film transistors T1 and T4 are turned off), a light emission current path is generated between the first intermediate electrode IE1 and the second intermediate electrode IE2, so that the G light emitting stack STg between the first intermediate electrode IE1 and the second intermediate electrode IE2 may emit light. Additionally, when the third and fourth thin film transistors T3 and T4 are turned on (and the first and second thin film transistors T1 and T2 are turned off), a light emission current path is generated between the second intermediate electrode IE2 and the cathode 169, so that the B light emitting stack STb between the second intermediate electrode IE2 and the cathode 169 may emit light.

Moreover, when the first and third thin film transistors T1 and T3 are turned on (and the second and fourth thin film transistors T2 and T4 are turned off), a light emission current path is generated between the anode 150 and the second intermediate electrode IE2, so that the R and G light emitting stacks STr and STg between the anode 150 and the second intermediate electrode IE2 may emit light together. Additionally, when the second and fourth thin film transistors T2 and T4 are turned on (and the first and third thin film transistors T1 and T3 are turned off), a light emission current path is generated between the first intermediate electrode IE1 and the cathode 169, so that the G and B light emitting stacks STg and STb between the first intermediate electrode IE1 and the cathode 169 may emit light together.

Moreover, when the first and fourth thin film transistors T1 and T4 are turned on (and the second and third thin film transistors T2 and T3 are turned off), a light emission current is generated between the anode 150 and the cathode 169, so that the R, G, and B light emitting stacks STr, STg, and STb between the anode 150 and the cathode 169 may emit light together.

Meanwhile, each of the first to fourth thin film transistors T1 to T4 disposed in each subpixel SP may include a gate electrode, a source electrode, a drain electrode, and a semiconductor layer.

Here, the semiconductor layer of each of the first to fourth thin film transistors T1 to T4 may be formed of, for example, amorphous silicon, polycrystalline silicon, or an oxide semiconductor material, but not limited thereto.

In addition, each of the first to fourth thin film transistors T1 to T4 may have a coplanar structure or an inverted staggered structure.

A passivation layer 135 may be formed on the thin film transistors T1 to T4 as an insulating layer formed of an insulating material. The passivation layer 135 may be formed in a single-layered structure or multi-layered structure.

In the passivation layer 135, first to fourth drain contact holes CHd1 to CHd4 may be formed to respectively expose the drain electrodes of the first to fourth thin film transistors T1 to T4.

The anode 150 may be formed on the passivation layer 135 for each subpixel SP (or in a unit of each subpixel SP).

The anode 150 may contact the drain electrode of the first thin film transistor T1 through the first drain contact hole CHd1.

A bank 160 may be formed on the anode 150 and the passivation layer 135 along a boundary of each subpixel SP (or a boundary between neighboring subpixels SP).

The bank 160 may be formed to cover an edge of the anode 150 disposed in each subpixel SP.

The bank 160 may be formed to substantially surround the subpixel SP along a periphery of each subpixel SP and may have a first opening OP1 therein. Through the first opening OP, the anode 150 of each subpixel SP may be exposed upwardly.

A partition wall MOH of an overhang structure may be formed on the bank 160. The partition wall MOH may function to separate elements constituting the light emitting diode OD.

In this regard, in the above-described first aspect, as shown in FIGS. 2 and 3, the partition wall OH, which has a one-stage (or one-step) overhang structure, may be formed to extend along both boundaries of the B subpixel SPb.

Differently, in this aspect, the partition wall MOH having a multi-stage (or multi-step) overhang structure may be formed along the boundary of each subpixel SP and surrounding the subpixel SP. Here, in this aspect, for convenience of explanation, a case where the partition wall MOH is formed in a three-stage overhang structure is taken as an example.

The partition wall MOH of the three-stage overhang structure may be formed on the bank 160 and have a second opening OP2 corresponding to the first opening OP1 of the bank 160.

The partition wall MOH may include a first partition wall (or first partition) MOH1 of an overhang structure stacked on the bank 160, a second partition wall (or second partition) MOH2 of an overhang structure stacked on the first partition wall MOH1, and a third partition wall (or third partition) MOH3 of an overhang structure stacked on the second partition wall MOH2.

The overall shape of the first to third partition walls MOH1 to MOH3 (i.e., the overall shape of the partition wall MOH) may be in the form of a three-stage overhang whose width increases upward.

For example, the first partition wall MOH1 implementing the first stage overhang structure may be configured to include a first part (or first, first part) MOH1_1, and a second part (or first, second part) MOH1_2 that is located on the first part MOH1_1 and has a larger size (or larger width or larger area) than the first part MOH1_1.

As such, the first partition wall MOH1, which is a structure formed by a combination of the first part MOH1_1, and the second part MOH1_2 that has a wider width than the first part MOH1_1 and protrudes outward, may be formed in the overhang structure. Accordingly, the second part MOH1_2 may have a first protrusion portion PP1 that protrudes outward from the first part MOH1_1.

The second partition wall MOH2 implementing the second stage overhang structure may be configured to include a first part (or second, first part) MOH2_1, and a second part (or second, second part) MOH2_2 that is located on the first part MOH2_1 and has a larger size (or larger width or larger area) than the first part MOH2_1.

As such, the second partition wall MOH2, which is a structure formed by a combination of the first part MOH2_1, and the second part MOH2_2 that has a wider width than the first part MOH2_1 and protrudes outward, may be formed in the overhang structure. Accordingly, the second part MOH2_2 may have a second protrusion portion PP2 that protrudes outward from the first part MOH2_1.

Here, the second protrusion portion PP2 of the second part MOH2_2 of the second partition wall MOH2 may extend and protrude further outward than the first protrusion portion PP1 of the second part MOH1_2 of the first partition wall MOH1 that is at a stage lower than the second partition wall MOH2.

Meanwhile, the first part MOH2_1 of the second partition wall MOH2 may have a width equal to or greater than that of the first part MOH1_1 of the first partition wall MOH1.

The third partition wall MOH3 implementing the third stage overhang structure may be configured to include a first part (or third, first part) MOH3_1, and a second part (or third, second part) MOH3_2 that is located on the first part MOH3_1 and has a larger size (or larger width or larger area) than the first part MOH3_1.

As such, the third partition MOH3, which is a structure formed by a combination of the first part MOH3_1, and the second part MOH3_2 that has a wider width than the first part MOH3_1 and protrudes outward, may be formed in the overhang structure. Accordingly, the second part MOH3_2 may have a third protrusion PP3 that protrudes outward from the first part MOH3_1.

Here, the third protrusion portion PP3 of the second part MOH3_2 of the third partition wall MOH3 may extend and protrude further outward than the second protrusion PP2 of the second part MOH2_2 of the second partition wall MOH2, which is a stage lower than the third partition wall MOH3.

Meanwhile, the first part MOH3_1 of the third partition wall MOH3 may have a width equal to or greater than that of the first part MOH2_1 of the second partition wall MOH2.

As above, the partition wall MOH having the multi-stage overhang structure may be configured in a form where the width of the overhang structure increases toward the top.

By using the partition wall MOH of the multi-stage overhang structure in this way, the stacked films constituting the light emitting diode OD of the tandem structure may be physically separated and patterned by subpixel SP.

Meanwhile, similar to the first aspect, a first connection electrode COE1 connected to the drain electrode of the second thin film transistor T2 may be formed on the bank 160 located at the boundary of each subpixel SP.

In this regard, for example, the first connection electrode COE1 may be formed on a tope surface of the bank 160 and may have a shape extending toward an inside of each subpixel SP. An outer portion of the first connection electrode COE1 may be positioned to be covered with the first partition wall MOH1 (more specifically, be covered with the first part MOH1_1).

As such, the first connection electrode COE1 may be exposed under the first protrusion portion PP1 of the first partition wall MOH1.

The first connection electrode COE1 may contact the drain electrode of the second thin film transistor T2 through the second drain contact hole CHd2 formed in the passivation layer 135 and the bank 160.

In addition, similar to the first connection electrode COE1, the second connection electrode COE2, which is connected to the drain electrode of the third thin film transistor T3, may be formed on a top surface of the first partition wall MOH1 (more specifically, a top surface of the second part MOH1_2).

In this regard, for example, the second connection electrode COE2 may be formed on the top surface of the first partition wall MOH1 and may have a shape extending toward the inside of each subpixel SP along the first protrusion portion PP1. An outer portion of the second connection electrode COE2 may be positioned to be covered with the second partition wall MOH2 (more specifically, be covered with the first part MOH2_1).

As such, the second connection electrode COE2 may be exposed under the second protrusion portion PP2 of the second partition wall MOH2.

The second connection electrode COE2 may contact the drain electrode of the third thin film transistor T3 through the third drain contact hole CHd3 formed in the passivation layer 135, the bank 160, and the first partition wall MOH1.

In addition, similar to the first or second connection electrode COE1 or COE2, the third connection electrode COE3, which is connected to the drain electrode of the fourth thin film transistor T4, may be formed on a top surface of the second partition wall MOH2 (more specifically, a top surface of the second part MOH2_2).

In this regard, for example, the third connection electrode COE3 may be formed on the top surface of the second partition wall MOH2 and may have a shape extending toward the inside of each subpixel SP along the second protrusion portion PP2. An outer portion of the third connection electrode COE3 may be positioned to be covered with the third partition wall MOH3 (more specifically, be covered with the first part MOH3_1).

As such, the third connection electrode COE3 may be exposed under the third protrusion portion PP3 of the third partition wall MOH3.

This third connection electrode COE3 may contact the drain electrode of the fourth thin film transistor T4 through the fourth drain contact hole CHd4 formed in the passivation layer 135, the bank 160, and the first and second partition walls MOH1 and MOH2.

A plurality of stacked films may be deposited on the substrate 101 having the partition wall MOH and the connection electrodes COE1 to COE3 to form the light emitting diode OD, so that the light emitting diode OD of the tandem structure may be formed for each subpixel SP (or formed in a unit of subpixel SP).

In this regard, for example, the light emitting diode OD may include R, G, and B light emitting stacks STr, STg, and STb stacked upward, the cathode 169 stacked on the B light emitting stack STb, the first charge generation layer CGL1 stacked between the R and G light emitting stacks STr and STg, and the second charge generation layer CGL2 stacked between the G and B light emitting stacks STg and STb. In addition, the first intermediate electrode IE1 may be formed between the first charge generation layer CGL1 and the G light emitting stack STg, and the second intermediate electrode IE2 may be formed between the second charge generation layer CGL2 and the B light emitting stack STb.

The stacked films constituting the light emitting diode OD may be formed in a structure where each subpixel SP is separated by the partition wall MOH.

In this regard, the R light emitting stacks STr may be separated with the partition wall MOH therebetween. Accordingly, the R light emitting stack STr may be formed on the anode 150 and the bank 160 of each subpixel SP.

Here, the R light emitting stack STr may be formed to expose at least a portion of the first connection electrode COE1 located below the partition wall MOH (more specifically, located below the first protrusion portion PP1 of the first partition wall MOH1). In this aspect, a case where the R light emitting stack STr is formed to cover an end of the first connection electrode COE1 is taken as an example.

Accordingly, when the R light emitting stack STr is formed by deposition, the first connection electrode COE1 may be exposed between the R light emitting stack STr and the first partition wall MOH1.

The first charge generation layer CGL1 formed on the R light emitting stack STr may also be formed in substantially the same shape as the R light emitting stack STr.

The first intermediate electrode IE1 formed on the first charge generation layer CGL1 may be formed to be separated for each subpixel SP (or in a unit of each subpixel SP) by the partition wall MOH, similar to the R light emitting stack STr and the first charge generation layer CGL1.

Here, the first intermediate electrode IE1 is formed to have a size (or width or area) larger than those of the R light emitting stack STr and the first charge generation layer CGL1 therebelow. Thus, the first intermediate electrode IE1 may have a shape extending outward while substantially covering the R light emitting stack STr and the first charge generation layer CGL1.

The first intermediate electrode IE1 may extend over the first connection electrode COE1 and contact the exposed first connection electrode COE1. Accordingly, the first intermediate electrode IE1 may be electrically connected to the second thin film transistor T2 via the first connection electrode COE1 and receive a light emission current.

On the first intermediate electrode IE1, the G light emitting stacks STg may be separated for each subpixel SP (or in a unit of each subpixel SP) with the partition wall MOH therebetween, similar to the R light emitting stack STr.

Here, the G light emitting stack STg may be formed to expose at least a portion of the second connection electrode COE2 located below the partition wall MOH (more specifically, located below the second protrusion portion PP2 of the second partition wall MOH2). In this aspect, a case where the G light emitting stack STg is formed to cover an end of the second connection electrode COE2 is taken as an example.

Accordingly, when the G light emitting stack STg is formed by deposition, the second connection electrode COE2 may be exposed between the G light emitting stack STg and the second partition wall MOH2.

The second charge generation layer CGL2 formed on the G light emitting stack STg may also be formed in substantially the same shape as the G light emitting stack STg.

The second intermediate electrode IE2 formed on the second charge generation layer CGL2 may be formed to be separated for each subpixel SP (or in a unit of each subpixel SP) by the partition wall MOH, similar to the G light emitting stack STg and the second charge generation layer CGL2.

Here, the second intermediate electrode IE2 is formed to have a size (or width or area) larger than the G light emitting stack STg and the second charge generation layer CGL2 therebelow. Thus, the second intermediate electrode IE2 may have a shape extending outward while substantially covering the G light emitting stack STg and the second charge generation layer CGL2.

The second intermediate electrode IE2 may extend over the second connection electrode COE2 and contact the exposed second connection electrode COE2. Accordingly, the second intermediate electrode IE2 may be electrically connected to the third thin film transistor T3 via the second connection electrode COE2 and receive a light emission current.

On the second intermediate electrode IE2, the B light emitting stacks STb may be separated for each subpixel SP (or in a unit of each subpixel SP) with the partition wall MOH therebetween, similar to the R and G light emitting stacks STr and STg.

Here, the B light emitting stack STb may be formed to expose at least a portion of the third connection electrode COE3 located below the partition wall MOH (more specifically, located below the third protrusion portion PP3 of the third partition wall MOH3). In this aspect, a case where the B light emitting stack STb is formed to cover an end of the third connection electrode COE3 is taken as an example.

Accordingly, when the B light emitting stack STb is formed by deposition, the third connection electrode COE3 may be exposed between the B light emitting stack STb and the third partition wall MOH3.

The cathode 169 formed on the B light emitting stack STb may be formed to be separated for each subpixel SP (or in a unit of each subpixel SP) by the partition wall MOH, similar to the B light emitting stack STb.

Here, the cathode 169 is formed to have a size (or width or area) larger than the B light emitting stack STb therebelow. Thus, the cathode 169 may have a shape extending outward while substantially covering the B light emitting stack STb.

This cathode 169 may extend over the third connection electrode COE3 and contact the exposed third connection electrode COE3. Accordingly, the cathode 169 may be electrically connected to the fourth thin film transistor T4 via the third connection electrode COE3 and receive a low-potential driving voltage.

As above, so that each of the first and second intermediate electrodes IE1 and IE2 and the cathode 169 may be formed with a larger area than the stacked film therebelow, each of these electrodes IE1, IE2 and 169 may be deposited at a smaller deposition angle than the stacked film therebelow.

Meanwhile, the thicknesses of the R, G, and B light emitting stacks STr, STg, and STb, and the first and second charge generation layers CGL1 and CGL2 may be set such that the second intermediate electrode IE2 and the cathode 169 may be stably connected to the corresponding second and third connection electrodes COE2 and COE3.

In this regard, for example, the thicknesses of the second charge generation layer CGL2 located below the second intermediate electrode IE2, and the G and R light emitting stacks STg and STr and the first charge generation layer CGL1 located below the second charge generation layer CGL2 may be set such that a height of a top surface of the second charge generation layer CGL2 (or G light emitting stack STg) corresponds to a height of a top surface of the first partition wall MOH1 (or is equal to or greater than the height of the top surface of the first partition wall MOH1). In this case, the second intermediate electrode IE2 stacked on the second charge generation layer CGL2 may extend over the second connection electrode COE2 formed on the top surface of the first partition wall MOH1 to implement a stable contact structure.

Similarly, the thickness of the B light emitting stack STb located below the cathode 169 may be set such that a height of a top surface of the B light emitting stack STb corresponds to a height of a top surface of the second partition wall MOH2 (or is equal to or greater than the height of the top surface of the second partition wall MOH2). In this case, the cathode 169 stacked on the B light emitting stack STb may extend over the third connection electrode COE3 formed on the top surface of the second partition wall MOH2 to implement a stable contact structure.

An encapsulation layer 170 may be formed substantially over the entire surface of the substrate 101 having the cathode 169 separated by the partition wall MOH of the three-stage overhang structure.

The encapsulation layer 170 may serve to improve reliability by blocking penetration of moisture or oxygen from an outside.

Unlike the first aspect, a color filter layer may not be formed on the encapsulation layer 170. In this regard, as mentioned above, each subpixel SP uses the light emitting stacks ST that may be individually driven, so that each subpixel SP is not limited to a specific color emission region but may function as a region capable of emitting various colors as needed. Thus, there is no need to form a specific color filter pattern for each subpixel SP.

Accordingly, the light emitting display device 10 of this aspect may not be provided with a color filter layer.

Meanwhile, an overcoat layer (or transparent layer) 180 may be formed on the encapsulation layer 170. The substrate 101 having the overcoat layer 180 may have a substantially flat surface.

FIGS. 10 to 12 are diagrams illustrating examples of various colors that may be implemented in a subpixel using a light emitting diode of a tandem structure according to the third aspect of the present disclosure.

Referring to FIG. 10, it shows a case where when each of the R, G, and B light emitting stacks STr, STg, and STb is singly driven for the light emitting diode OD of the subpixel SP, red, green, and blue that are the primary colors may be implemented.

In this regard, for example, when the R light emitting stack STr is individually driven by forming a light emission current path between the anode 150 and the first intermediate electrode IE1, the corresponding red light may be emitted and output. Additionally, when the G light emitting stack STg is individually driven by forming a light emission current path between the first intermediate electrode IE1 and the second intermediate electrode IE2, the corresponding green light may be emitted and output. Additionally, when the B light emitting stack STb is individually driven by forming a light emission current path between the second intermediate electrode IE2 and the cathode 169, the corresponding blue light may be emitted and output.

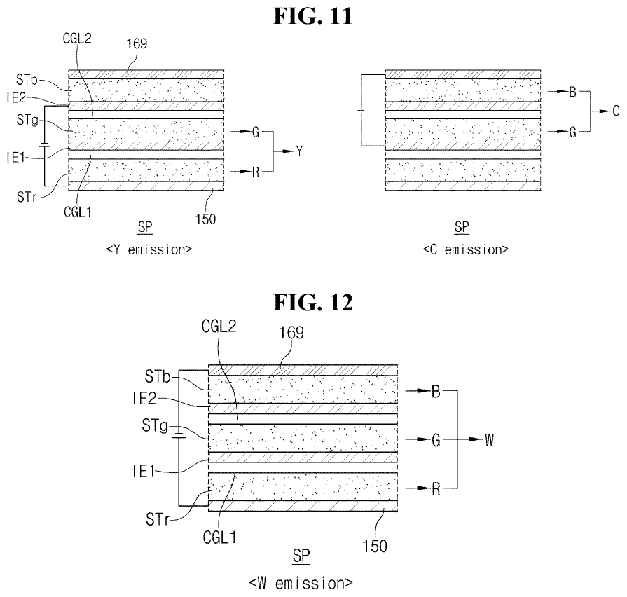

Referring to FIG. 11, it shows a case where when two adjacent stacks among the R, G, and B light emitting stacks STr, STg, and STb are driven in combination for the light emitting diode OD of the subpixel SP, yellow and cyan that are the mixed colors by the combination may be implemented.

In this regard, for example, when the R and G light emitting stacks STr and STg are driven together by forming a light emission current path between the anode 150 and the second intermediate electrode IE2, yellow light that is the mixed color of red and green may be emitted and output. Additionally, when the G and B light emitting stacks STg and STb are driven together by forming a light emission current path between the first intermediate electrode IE1 and the cathode 169, cyan light that is the mixed color of green and blue may be emitted and output.

Referring to FIG. 12, it shows a case where when all the R, G, and B light emitting stacks STr, STg, and STb are driven in combination for the light emitting diode OD of the subpixel SP, white light that is the mixed color by the combination may be implemented.

In this regard, for example, when the R, G, and B light emitting stacks STr, STg, and STb are driven together by forming a light emission current path between the anode 150 and the cathode 169, white light that is the mixed color of red light, green light, and blue light may be emitted and output.

As described above, according to aspects of the present disclosure, when using the light emitting diode of the tandem structure, the first and second light emitting stacks respectively emitting yellow and blue light, and the intermediate electrode disposed between the first and second light emitting stacks which constitute the light emitting diode may be separated by the partition walls of the overhang structure disposed along both boundaries of the B subpixel, and the intermediate electrode of the B subpixel may be configured to receive an individual driving current.

Accordingly, in the B subpixel, blue light may be emitted and output by individually driving the second light emitting stack without driving the first light emitting stack, so that power consumption may be reduced and low power driving is possible. In addition, since there is no need to form a blue color filter pattern in the B subpixel, a material cost of a color filter pattern may be reduced.

Moreover, according to aspects of the present disclosure, when using the light emitting diode of the tandem structure, the first, second, and third light emitting stacks respectively emitting red, green, and blue, and the first and second intermediate electrodes disposed between the first, second, and third light emitting stacks which constitute the light emitting diode may be separated for each subpixel (or in a unit of each subpixel) by the partition wall of the multi-stage overhang structure disposed around the subpixel, and the first and second intermediate electrodes and the cathode may be configured to receive individual driving currents.

Accordingly, the first, second, and third light emitting stacks in each subpixel may be driven individually and be driven in combination, so that power consumption may be reduced and low power driving is possible.

In addition, since each subpixel is not limited to a specific color emission region and may function as a region that may emit various colors as needed, the color image expression performance of the light emitting display device may be maximized. In addition, since there is no need to form a specific color filter pattern in every subpixel, there is no need to form a color filter layer, and a material cost of a color filter pattern may be reduced to the maximum.

It will be apparent to those skilled in the art that various modifications and variation may be made in the present disclosure without departing from the spirit or scope of the disclosure. Thus, it is intended that the present disclosure cover the modifications and variations of this disclosure provided they come within the scope of the appended claims and their equivalents.

What is claimed is:

1. A light emitting display device, comprising:
a substrate including a display region in which first, second, and third subpixels of different colors are arranged;
a first electrode disposed in each of the first, second, and third subpixels;
a partition wall of an overhang structure which extends along a boundary between the first subpixel and the second and third subpixels, and includes a protrusion portion protruding outward;
a connection electrode disposed under the protrusion portion of the partition wall at the boundary of the first subpixel;
first and second light emitting stacks disposed on the first electrode of the first subpixel and on the first electrodes of the second and third subpixels, a charge generation layer between the first and second light emitting stacks, and a second electrode on the second light emitting stack, wherein the first and second light emitting stacks, the charge generation layer, and the second electrode are separated by the partitional wall; and
an intermediate electrode which is separated by the partition wall and disposed in the first subpixel, is located between the charge generation layer and the second light emitting stack in the first subpixel, and is connected to the connection electrode.

2. The light emitting display device of claim 1, further comprising a color filter layer disposed on the second electrode,
wherein the color filter layer includes first and second color filter patterns that correspond to the second and third subpixels and generate the colors of the second and third subpixels,
respectively, and a transparent pattern corresponding to the first subpixel.

3. The light emitting display device of claim 1, further comprising a bank disposed along a boundary of each of the first, second, and third subpixels,
wherein the partition wall and the connection electrode are located on the bank at the boundary of the first subpixel, and
wherein the first light emitting stack of the first subpixel covers an end of the connection electrode to expose a part of the connection electrode, and the intermediate electrode extends outside the first light emitting stack and contacts the exposed part of the connection electrode.

4. The light emitting display device of claim 1, wherein the first subpixel has a thin film transistor connected to the connection electrode, and each of the second and third subpixels is provided with a thin film transistor connected to the first electrode,
wherein in the first subpixel, the first light emitting stack is in a light emission off state and the second light emitting stack emits light, and
wherein in each of the second and third subpixels, the first and second light emitting stacks emit light together.

5. The light emitting display device of claim 1, wherein each of the second electrode of the first subpixel and the second electrode of the second and third subpixels extends along the partition wall, and is connected to a voltage line disposed in a non-display region outside the display region to receive a low-potential driving voltage.

6. The light emitting display device of claim 1, further comprising a dummy intermediate electrode which is separated from the intermediate electrode by the partition wall and disposed in the second and third subpixels, and is located between the charge generation layer and the second light emitting stack in the second and third subpixels.

7. The light emitting display device of claim 1, wherein the second light emitting stack includes a second, first light emitting stack and a second, second light emitting stack on the second, first light emitting stack, and
wherein the first, second, and third subpixels are blue, red, and green subpixels, respectively.

8. The light emitting display device of claim 1, wherein the first, second, and third subpixels are blue, red, and green subpixels, respectively.

9. The light emitting display device of claim 1, wherein the partition wall is formed to extend in a column direction along both boundaries of the first subpixel, and the partition wall is not formed along a boundary between the second and third subpixels.

10. The light emitting display device of claim 1, wherein the intermediate electrode is continuously formed along the first subpixels arranged in the same column line.

11. A light emitting display device, comprising:
a substrate including a display region in which a plurality of subpixels are arranged;
a first electrode disposed for each subpixel;
a partition wall disposed along a boundary of the subpixel, and includes first to third partition walls which are stacked upward, each have an overhang structure, and respectively include first to third protrusion portions protruding outward;
a first connection electrode formed below the first protrusion portion, a second connection electrode disposed on a top surface of the first protrusion portion, and a third connection electrode disposed on a top surface of the second protrusion portion; and
first, second, and third light emitting stacks stacked on the first electrode and emitting different colors, a second electrode on the third light emitting stack, a first charge generation layer between the first and second light emitting stacks, a second charge generation layer between the second and third light emitting stacks, a first intermediate electrode between the first charge generation layer and the second light emitting stack, and a second intermediate electrode between the second charge generation layer and the third light emitting stack,
wherein the first to third light emitting stacks, the first and second charge generation layers, the first and second intermediate electrodes, and the second electrode are separated for each subpixel by the partitional wall, and
wherein the first and second intermediate electrodes and the second electrode are respectively connected to the first, second and third connection electrodes.

12. The light emitting display device of claim 11, further comprising a bank disposed along the boundary of the subpixel,
wherein the partition wall and the first connection electrode are located on the bank, and
wherein the first light emitting stack covers an end of the first connection electrode to expose a part of the first connection electrode, and the first intermediate electrode extends outside the first light emitting stack and contacts the exposed part of the first connection electrode.

13. The light emitting display device of claim 11, wherein the second light emitting stack covers an end of the second connection electrode to expose a part of the second connection electrode, and the second intermediate electrode extends outside the second light emitting stack and contacts the exposed part of the second connection electrode.

14. The light emitting display device of claim 11, wherein the third light emitting stack covers an end of the third connection electrode to expose a part of the third connection electrode, and the second electrode extends outside the third light emitting stack and contacts the exposed part of the third connection electrode.

15. The light emitting display device of claim 11, wherein a height of a top surface of the second light emitting stack or the second charge generation layer is equal to or greater than a height of a top surface of the first partition wall, and
wherein a height of a top surface of the third light emitting stack is equal to or greater than a height of a top surface of the second partition wall; and further wherein the respective heights are a height above the substrate.

16. The light emitting display device of claim 11, wherein the subpixel has first to fourth thin film transistors respectively connected to the first electrode and the first to third connection electrodes.

17. The light emitting display device of claim 11, wherein the first to third light emitting stacks emit light individually, or two or more of the first to third light emitting stacks emit light together.

18. The light emitting display device of claim 11, wherein the first to third light emitting stacks are different light emitting stacks among red, green, and blue light emitting stacks.

19. The light emitting display device of claim 11, wherein the second protrusion portion extends and protrudes further outward than the first protrusion portion, and the third protrusion portion extends and protrudes further outward than the second protrusion.
